(19) United States
(12) Patent Application Publication
(10) Pub. No.: US 2025/0105129 A1
(43) Pub. Date: Mar. 27, 2025

(54) LAMINATE CARRIER WITH EMBEDDED ELECTRONIC COMPONENT ELECTRICALLY COUPLED WITH PROTRUDING PIN

(71) Applicant: Infineon Technologies AG, Neubiberg (DE)

(72) Inventors: Urban MEDIC, Logatec (SI); Christian Stefan RAINER, Magdalensberg (AT); Thomas GEBHARD, Villach (AT); Eslam Mohammed ABDELHAMID, Villach (AT)

(73) Assignee: Infineon Technologies AG, Neubiberg (DE)

(21) Appl. No.: 18/806,998

(22) Filed: Aug. 16, 2024

(30) Foreign Application Priority Data
Sep. 21, 2023 (DE) 10 2023 125 592.4

(51) Int. Cl. H01L 23/498; H01L 23/00; H01L 23/31; H01L 23/367; H01L 25/065

(52) U.S. Cl. CPC H01L 23/49838; H01L 23/315; H01L 23/3677; H01L 23/49816; H01L 23/49827; H01L 25/0655; H01L 24/16; H01L 2224/1623; H01L 2924/37001

(57) ABSTRACT

An electronic device is disclosed. In one example, the electronic device comprises a laminate carrier comprising a plurality of laminated layers, an electronic component embedded in the laminate carrier, and an at least partially electrically conductive pin extending partially inside the laminate carrier and partially protruding beyond the laminate carrier. The pin is electrically coupled with the electronic component.

### CROSS-REFERENCE TO RELATED APPLICATION

This Utility Patent application claims priority to German Patent Application No. 10 2023 125 592.4 filed Sep. 21, 2023, which is incorporated herein by reference.

### BACKGROUND

The present invention relates to an electronic device, and to a method of manufacturing an electronic device.

A package may comprise an electronic component, such as a semiconductor chip, mounted on a carrier, such as a leadframe. Packages may be embodied as encapsulated electronic component mounted on a carrier with electrical connects extending out of the encapsulant and being coupled with an electronic periphery. A mold compound may be used as encapsulant. In a package, the electronic component may be connected to the carrier by a clip or a bond wire.

Also packages with electronic component embedded in a laminate-type carrier are known.

However, connection of a laminate package with an electronic periphery is still a process involving a high effort.

### SUMMARY

There may be a need to provide a laminate-type electronic device being connectable with an electronic periphery in a simple way.

According to an exemplary embodiment, an electronic device is provided which comprises a laminate carrier comprising a plurality of laminated layers, an electronic component embedded in the laminate carrier, and an at least partially electrically conductive pin extending partially inside the laminate carrier and partially protruding beyond the laminate carrier, wherein the pin is electrically coupled (for example is electromechanically coupled) with the electronic component.

According to another exemplary embodiment, a method of manufacturing an electronic device is provided, the method comprising embedding an electronic component in a laminate carrier which comprises a plurality of laminated layers, forming an at least partially electrically conductive pin which extends partially inside the laminate carrier and partially protrudes beyond the laminate carrier, and electrically coupling the pin with the electronic component.

According to an exemplary embodiment, a laminate-type package is provided which is based on a laminate carrier, which may be a laminated layer stack. For example, the laminate carrier may comprise an organic material such as prepreg which may be interconnected with one or more metal layers such as copper foils to form a laminate. Embedded in an interior of the laminate body may be an electronic component, such as a semiconductor chip. It may be desired to connect such an arrangement electrically and mechanically to an electronic periphery. Advantageously, this may be achieved by an only partially or entirely electrically conductive pin which is located partially inside the laminate carrier and partially outside of the laminate carrier so as to be accessible for both electric and mechanical connection purposes. Beneficially, the pin may be electrically connected with the embedded electronic component so that an electric coupling of the embedded electronic component with an electronic periphery may be accomplished by the pin. Hence, the protruding interconnection pin fixed inside the laminate carrier may have a mechanical and electrical double function, since it may promote a mechanical connection of the electronic device with another electronic member while simultaneously establishing an electric coupling of the embedded electronic component with the electronic member by the pin. By taking this measure, a laminate package is provided which can be connected with an electronic periphery in an easy fashion.

### BRIEF DESCRIPTION OF THE DRAWINGS

The accompanying drawings, which are included to provide a further understanding of exemplary embodiments of the invention and constitute a part of the specification, illustrate exemplary embodiments of the invention.

In the drawings:

FIG. 1 shows a cross-sectional view of an electronic device according to an exemplary embodiment.

FIG. 2 shows a cross-sectional view of an electronic device according to another exemplary embodiment.

FIG. 3 shows a cross-sectional view of an electronic device according to another exemplary embodiment.

FIG. 4 shows a cross-sectional view of an electronic device according to another exemplary embodiment.

FIG. 5 shows a cross-sectional view of an electronic device according to another exemplary embodiment.

FIG. 6 shows a cross-sectional view of an electronic device according to another exemplary embodiment.

FIG. 7 shows a cross-sectional view of an electronic device according to another exemplary embodiment.

FIG. 8 shows a cross-sectional view of an electronic device according to another exemplary embodiment.

FIG. 9 shows a cross-sectional view of an electronic device according to another exemplary embodiment.

FIG. 10 shows a cross-sectional view of an electronic device according to another exemplary embodiment.

### DETAILED DESCRIPTION OF EXEMPLARY EMBODIMENTS

There may be a need to provide a laminate-type electronic device being connectable with an electronic periphery in a simple way.

According to an exemplary embodiment, an electronic device is provided which comprises a laminate carrier comprising a plurality of laminated layers, an electronic component embedded in the laminate carrier, and an at least partially electrically conductive pin extending partially inside the laminate carrier and partially protruding beyond the laminate carrier, wherein the pin is electrically coupled (for example is electromechanically coupled) with the electronic component.

According to another exemplary embodiment, a method of manufacturing an electronic device is provided, the method comprising embedding an electronic component in a laminate carrier which comprises a plurality of laminated layers, forming an at least partially electrically conductive pin which extends partially inside the laminate carrier and partially protrudes beyond the laminate carrier, and electrically coupling the pin with the electronic component.

According to an exemplary embodiment, a laminate-type package is provided which is based on a laminate carrier, which may be a laminated layer stack. For example, the laminate carrier may comprise an organic material such as prepreg which may be interconnected with one or more metal layers such as copper foils to form a laminate. Embedded in an interior of the laminate body may be an electronic component, such as a semiconductor chip. It may be desired to connect such an arrangement electrically and mechanically to an electronic periphery. Advantageously, this may be achieved by an only partially or entirely electrically conductive pin which is located partially inside the laminate carrier and partially outside of the laminate carrier so as to be accessible for both electric and mechanical connection purposes. Beneficially, the pin may be electrically connected with the embedded electronic component so that an electric coupling of the embedded electronic component with an electronic periphery may be accomplished by the pin. Hence, the protruding interconnection pin fixed inside the laminate carrier may have a mechanical and electrical double function, since it may promote a mechanical connection of the electronic device with another electronic member while simultaneously establishing an electric coupling of the embedded electronic component with the electronic member by the pin. By taking this measure, a laminate package is provided which can be connected with an electronic periphery in an easy fashion.

### Description of further exemplary embodiments

In the following, further exemplary embodiments of the electronic device and the method will be explained.

In the context of the present application, the term “electronic device” may particularly denote a device with electronic functionality and which may comprise one or more electronic components mounted inside a laminate carrier. The electronic device may be suitable or intended for being electrically and mechanically coupled with another electronic member.

In the context of the present application, the term “laminate carrier” may particularly denote a flat body (such as a sheet or plate) formed by multiple interconnected laminate layers, i.e. layers which can be or which are interconnected by lamination. In particular, a laminate carrier may comprise a material that is suitable for sticking several laminate layers, for instance made of the same material, together. Hence, a laminate carrier may be a sheet shaped body made of one or multiple laminable or laminated layers. Said laminate layers may be connected or configured to be connectable with other layers by lamination. Lamination may denote a connection of laminable layers using elevated temperature, optionally accompanied by an additional mechanical pressure applied to stacked laminate layers. In particular, such a laminate carrier may be a pressed multilayer stack of one or more dielectric organic layers and/or one or more metallic foils. One or more dielectric laminate layers may be for example prepreg layers. Prepreg is a material which comprises a resin, optionally with glass fibres therein. The laminate carrier may also comprise one or more metal foils, which may be copper foils. More generally, the laminate carrier may comprise at least one dielectric layer which is capable of curing, polymerizing and/or cross-linking during a lamination process, thereby contributing to an adhesion force between multiple layers of a multilayer laminate.

In particular, a laminate material or material of the laminate carrier may be an epoxy resin or another polymer (like polyimide) or another insulating material filled with filler particles, in particular glass particles, more particularly glass fibers. Such a material may be provided as prepreg, i.e. as a sheet in which the epoxy resin is not or not fully cured, so that it can become liquid by supplying thermal energy. In a laminate carrier, such a prepreg sheet may be combined with one or more copper foils which can be attached upon lamination. Resin Coated Copper (RCC) is a combination of a copper foil and an uncured epoxy resin without glass fibers.

In the context of the present application, the term “electronic component” may in particular encompass a semiconductor chip (in particular a power semiconductor chip), an active electronic device (such as a transistor), a passive electronic device (such as a capacitance or an inductance or an ohmic resistance), a sensor (such as a microphone, a light sensor or a gas sensor), an actuator (for instance a loudspeaker), and/or a microelectromechanical system (MEMS). In particular, the electronic component may be a semiconductor chip having at least one integrated circuit element (such as a diode or a transistor) in a surface portion thereof. The electronic component may be a bare die or may be already packaged or encapsulated.

In the context of the present application, the term “embedded electronic component” may in particular an electronic component which is arranged inside of the laminate carrier, for example with or without surface access.

In the context of the present application, the term “pin” may in particular denote an oblong slender piece of metal used for fastening, supporting and/or attaching the laminate carrier with another electronic member while simultaneously establishing an electric coupling of an electrically connected embedded electronic component with the other electronic member. For example, a ratio between a length of the pin and a maximum diameter of the pin may be at least 2, for example at least 5. The pin may extend straight and perpendicular to a main surface of the laminate carrier. A pin may have a continuous diameter along its entire extension or may be composed of at least two different sections with different diameters.

In an embodiment, the pin is fixed in the laminate carrier by press-fitting. Correspondingly, the method may comprise inserting and fixing the pin in the laminate carrier by press-fitting. Press-fitting may denote a medium-free (in particular solder-free) electrical-mechanical connection between pin and laminate carrier. For this purpose, a press-fitting pin may be pressed into the laminate carrier, for instance in an accommodation hole formed therein or without pre-drilling. At one or more contact points between a metallic pin and a metallic section of the laminate carrier, connection zones may be optionally created by cold welding between the contact materials. In particular, there are the following two press-fitting contacts: A rigid or solid press-fitting may denote a press-fitting connection using a rigid or solid pin. A compliant press-fitting may use an elastically deformable or plastically deformable pin.

However, the pin can also be connected to an alternate component (for example an SMD (surface mounted device) resistor) on top of the board.

In an embodiment, the electronic device comprises an anchor block which is arranged in the laminate carrier and which has a hole (such as a blind hole) accommodating an end portion of the pin for anchoring the pin in the laminate carrier. An anchor block may be a metallic block with accommodation hole (in particular blind hole) for accommodating the pin therein. For example, such an anchor block may have a cross-sectional area in a plane parallel to a main surface of the laminate carrier which is for example at least twice, preferably at least three times, of a cross-sectional area of the anchored pin. Such an anchor block may significantly enhance stability and anchoring force of the pin in the laminate carrier. Thus, the use of an anchor block may significantly improve the robustness of the electronic device and the reliability of its electromechanical connection with another electronic member. For example, the anchor block may be a metal block, for instance a copper block, with an accommodation hole configured for accommodating an end section of the pin. Preferably, the accommodation hole may be a blind hole so that the pin may be inserted into the accommodation hole of the anchor block by press-fitting without the risk of destroying laminate carrier or excessively inserting the pin beyond a maximum desired depth.

Correspondingly, the method may comprise embedding in the laminate carrier the electronic component and an anchor block for anchoring the pin. Embedding the electronic component and an anchor block may be done at the same vertical level in the laminate carrier. The anchor or anchor block can also be embedded between different pairs of layers than the electronic component.

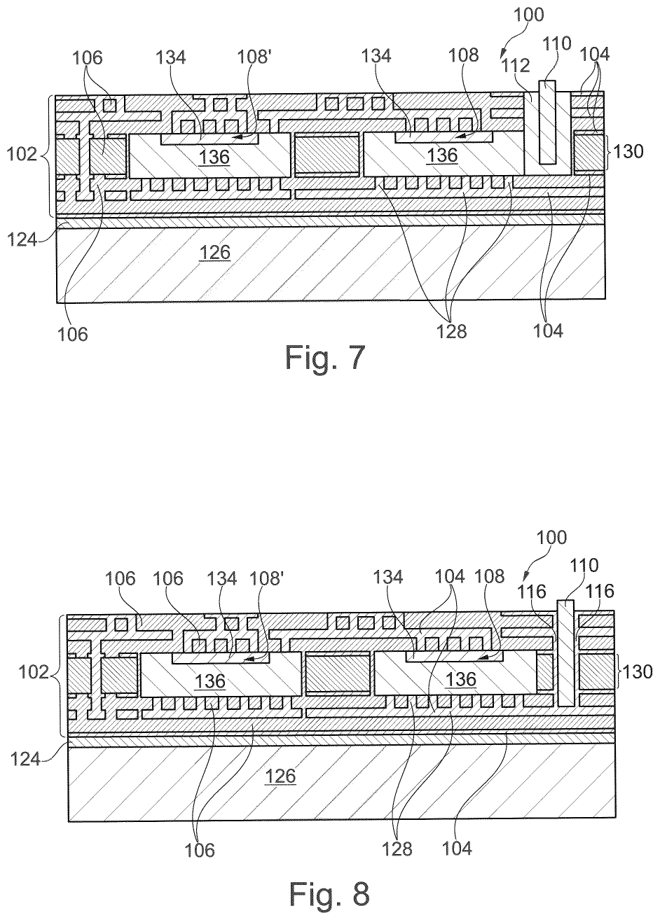

In an embodiment, the anchor block is directly electrically coupled with the electronic component, for example by mutually contacting sidewalls of the anchor block and of the electronic component (see for example FIG. 7). In particular, a sidewall of the anchor block may be in direct physical contact with a sidewall of the electronic component. This may ensure short electric connection paths and consequently low signal losses and high signal integrity.

In an embodiment, the anchor block is electrically coupled with the electronic component via at least one electrically conductive layer of the laminate carrier. An electric signal path may then be from said electronic component, via said electrically conductive laminate layer, via the anchor block up to the pin, and from there to the electronic periphery of the electronic device, or vice versa. For example, said electrically conductive layer may form part of a redistribution layer of the laminate carrier. In the context of the present application, the term “redistribution layer” may particularly denote a layer or arrangement of layers with electrically conductive and electrically insulating portions which accomplishes an interface function between the small dimensions of electronic components and larger dimensions of the laminate carrier. Forming such a redistribution layer in the laminate carrier and connecting it with the anchor block may simplify a connection of the embedded electronic component with an electronic environment, such as a connection board like a PCB.

In an embodiment, the anchor block forms part of the electronic component (see for example FIG. 4). For example, the electronic component may be embodied as a bare die assembled in a cavity of a metal block. In such a configuration, an additional blind hole may be formed in the metal block (for example laterally from the cavity) for accommodating an end section of the pin therein. Simply inserting the pin in the blind hole may then establish a mechanical connection between pin and anchor block section of the electronic component and may simultaneously establish an electric connection between the pin and the bare die of the electronic component. Advantageously, this may lead to short electric paths, low losses and high signal integrity.

In an embodiment, the electronic device comprises a strain relief structure arranged in the laminate carrier between the anchor block and a portion of the pin protruding beyond the laminate carrier. To put it shortly, a strain relief structure may render the electronic device robust against strain. For example, a strain relief structure may be embodied as a perforated metal block arranged in a surface portion of the laminate carrier. Descriptively speaking, a strain relief structure may be configured for preventing the pin and/or a surrounding portion of the laminate carrier from breaking when exerting a mechanical force, moving or bending the pin relatively to the laminate carrier. Preferably, the strain relief structure may be configured as a solid block (for example made of metal) with through hole in a cavity of the laminate carrier with surface access, wherein the pin may be guided through said through hole. Such an embodiment may lead to a highly robust configuration of the arrangement composed of embedded anchor block, strain relief structure with surface access and pin guided at least partially through both of them so as to protrude beyond an upper main surface of the laminate carrier. However, other embodiments of a strain relief structure may be possible as well.

In an embodiment, the electronic device comprises an anchor sleeve (such as a plated through hole via) which in arranged in or forms part of the laminate carrier and which has a blind hole accommodating an end portion of the pin or which has a through hole accommodating a portion of the pin. Rather than embedding an anchor block in the laminate carrier, it may thus be possible to provide a hollow cylindrical anchor sleeve as an integral part of the laminate carrier. Such an anchor sleeve may be made of material of an electrically conductive structure of the laminate carrier. For instance, the anchor sleeve may be embodied as a metal plated hole formed by lining the walls of a hole formed in the laminate carrier by a metallic coating, for example a copper coating. Advantageously, such an anchor sleeve may provide an anchoring function with very small space consumption and with only very low additional manufacturing effort.

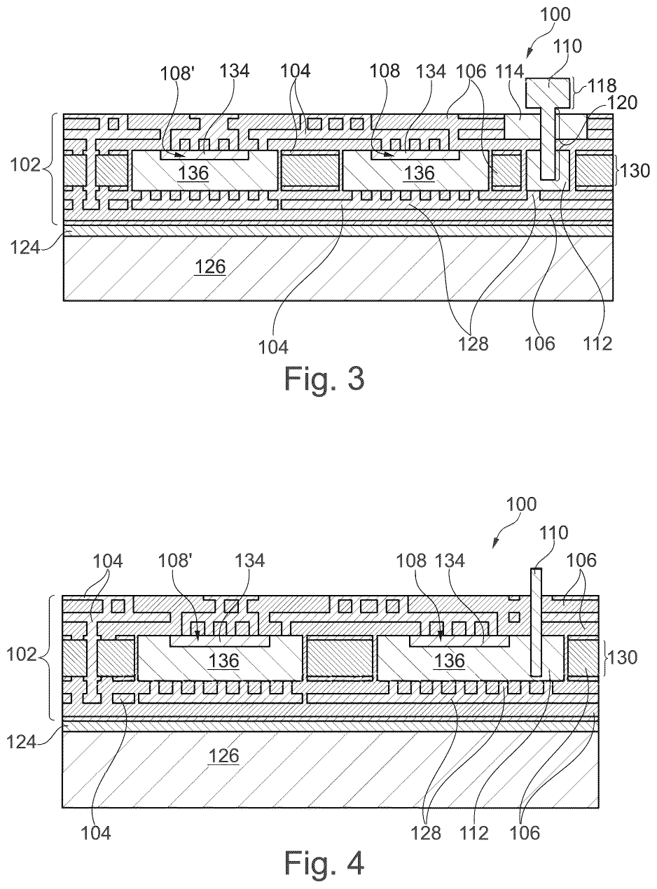

In an embodiment, the pin has a wider portion (i.e. a portion with larger diameter) at least partially protruding beyond the laminate carrier and a narrower portion (i.e. a portion with smaller diameter) at least partially inside the laminate carrier (see for example FIG. 2 or FIG. 3). Thus, the mechanical robustness of such a pin outside of the laminate carrier, where the pin is unprotected, may be strengthened.

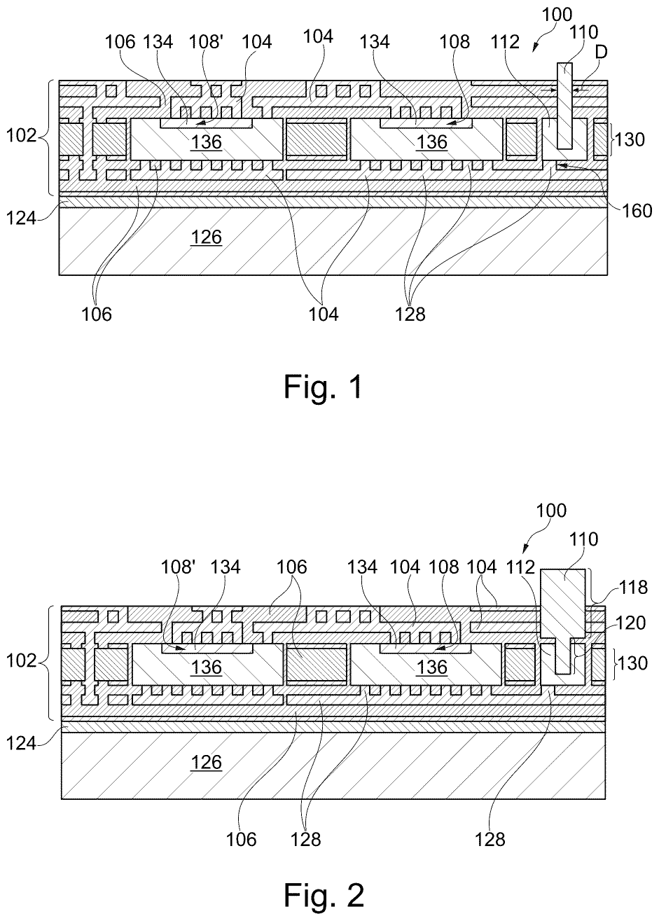

In another embodiment, the pin has a constant diameter over its entire extension. In particular, a horizontal cross-sectional shape of the pin at different height levels may be the same over the entire vertical extension of the pin. Such an embodiment is shown, for instance, in FIG. 1. Such a pin may be simple what concerns manufacture, handling and assembly. In another embodiment, the diameter of the pin may vary along its axial extension (see for instance FIG. 2).

In an embodiment, the electronic device is configured so that electric signals and/or electric power is transmitted by the pin during operation of the electronic device. Thus, the pin may not only mechanically couple the electronic device with another electronic member (for instance for establishing a board-to-board interconnection), but additionally the pin may also be interconnected and configured to carry electric signals and/or electric power between the electronic device and the other electronic member during use.

In an embodiment, the electronic device comprises at least one further electronic component embedded in the laminate carrier. Thus, a plurality of electronic components may be embedded in the laminate carrier. For example, different embedded electronic components of the laminate carrier may be arranged side-by-side at the same vertical level. Additionally or alternatively, different embedded electronic components of the laminate carrier may be vertically stacked inside of the laminate carrier. Furthermore, it may be possible to surface mount at least one electronic component on the laminate carrier in addition to the one or more embedded electronic components.

In an embodiment, the electronic device comprises at least one further at least partially electrically conductive pin extending partially inside the laminate carrier and partially protruding beyond the laminate carrier and being electrically coupled with the electronic component and/or with at least one further electronic component embedded in the laminate carrier. Thus, the laminate carrier may comprise an array of pins each having the above mentioned features. For instance, different pins may be arranged parallel to each other partially inside and partially outside of the laminate carrier. By an arrangement of a plurality of pins (for instance at least four pins, or at least 10 pins) being anchored inside and protruding beyond one and the same laminate carrier, a mechanically highly robust board-to-board interconnection may be realized which supports even sophisticated electronic applications.

In an embodiment, the electronic device comprises a thermal interface layer and/or a heat sink arranged at (in particular on and/or above) a main surface of the laminate carrier facing away from a portion of the pin protruding beyond the laminate carrier. The thermal interface layer may comprise a thermal interface material (TIM). Such a thermal interface material may for instance be a thermal paste providing a thermal coupling with a heat sink with low thermal resistance in between. The thermal interface layer may contribute to a removal of heat generated by the embedded electronic component(s) during operation of the package. An appropriate heat sink may be a heat dissipation body, which may be made of a highly thermally conductive material such as copper or aluminum. For instance, such a heat sink may have a base body facing said thermal interface body and may have a plurality of cooling fins extending from the base body and in parallel to each another so as to remove the heat towards the environment. Advantageously, the attachment of a thermal interface layer plus heat sink on a main surface of the laminate carrier facing away from an opposing other main surface of the laminate carrier at which the one or more pins protrude(s) allows to spatially separate an electromechanical interconnection from heat dissipation. Heat may be dissipated from the embedded electronic component(s) via the thermal interface layer to the heat sink and from there to an environment. The electromechanical connection of the electronic device with an electronic periphery may be established by the pin(s) extending up to another electronic member. Such a spatial and functional separation allows to use both opposing main surfaces of the laminate carrier in a highly efficient way.

In an embodiment, an end portion of the pin extending into the laminate carrier has a free end ending in the laminate carrier. Such an anchoring of the pin(s) in an interior of the laminate carrier may lead to a highly robust and stable configuration while simultaneously allowing to achieve short electrical paths supported by the pin(s). Furthermore, such a configuration may avoid a pin protruding towards or even beyond a heat sink-side of the laminate carrier, so that one main surface of the laminate carrier can be used solely for heat removal without the need of taking care about a pin protruding there.

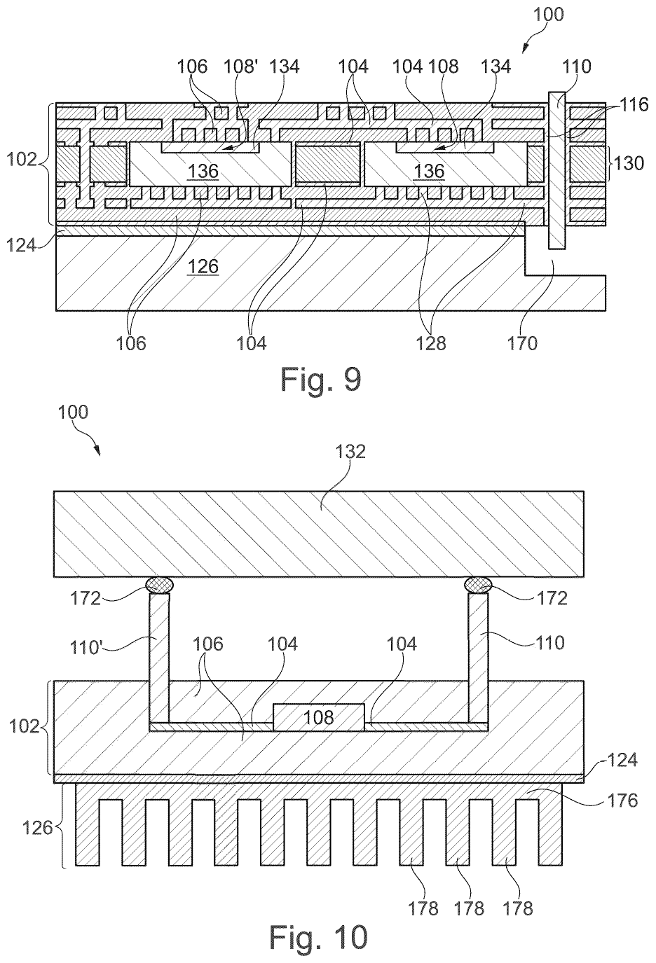

In another embodiment, both opposing end portions of the pin protrude beyond the laminate carrier, and a portion of the pin extends inside the laminate carrier (see for instance FIG. 9). Care should be taken in such a configuration that an undesired interaction between a heat sink and the protruding pin can be avoided, for instance by cutting out a piece of the heat sink for accommodating a pin end in a corresponding recess.

In an embodiment, the pin is directly electrically coupled with the electronic component (see FIG. 6). In such an embodiment, the pin may directly contact a pad or terminal or a conductive body of the electronic component, which may lead to a very short electrically conductive path and consequently low losses.

In another embodiment, the pin is electrically coupled with the electronic component via an at least partially electrically conductive anchor block in which the pin is inserted. The electric coupling between the electronic component and the anchor block may be direct (see FIG. 7). This may provide a mechanically highly stable electronic device which may be used even under harsh conditions.

In an embodiment, the pin is electrically coupled with the electronic component via at least one electrically conductive layer of the laminate carrier (see FIG. 1), for example via a redistribution layer of the laminate carrier. Such an embodiment may make use of one or more electrically conductive layers of the laminate carrier for electrically and mechanically connecting the pin. Such a configuration may be combined with an anchor block (see FIG. 1) or with an anchor sleeve (see FIG. 8).

In an embodiment, the electronic component is embedded in a core in an interior of the laminate carrier. For instance, the electronic component is embedded in a central core of the laminate carrier. For example, such a core may be a support sheet in the laminate carrier, for instance made of FR4 material. For instance, such a core may be cladded with copper layers. Embedding the one or more electronic components in the core may provide a highly symmetric arrangement, which may suppress warpage. It is also possible that a plurality of electronic components are embedded in the core of the laminate carrier.

In an embodiment, an anchor block can also be placed inside the same core as the at least one electronic component or in another core of the laminate carrier. Different PCB assemblies with separate cores can be laminated together.

In an embodiment, the electronic device comprises an electronic member being coupled (for example being electromechanically coupled) with the laminate carrier by a portion of the pin protruding beyond the laminate carrier. For example, the electronic member comprises at least one of an electronic board (such as a printed circuit board, PCB), an electric cable, and a metallic block (such as a bulk connector).

In an embodiment, the coupling between the electronic member and the laminate carrier comprises at least one of the group comprising a solder coupling, a screw coupling, a press fit coupling, and a plug-in coupling. In case of a solder coupling, a solder may be used for connecting the pin with the electronic member. For establishing a screw coupling, one of the pin and the electronic member may be equipped with an external thread and the other one with an internal thread. Also a press fit coupling between the pin and the electronic member may be established. In yet another embodiment, a plug-in coupling may be created by plugging the pin into an accommodation opening of the electronic member, or vice versa. Other connection technologies may be implemented as well.

In an embodiment, the pin is a solid pin or a sleeve. Hence, the pin may be hollow or free of interior voids.

In an embodiment, the pin has a springy portion. This may allow to assemble the pin with reasonable assembly force.

In an embodiment, the electronic component is a bare power semiconductor die. In the context of the present application, the term “bare die” may be a non-encapsulated semiconductor chip. A “power semiconductor die” may be a semiconductor chip configured for providing an electronic power application.

In an embodiment, the electronic component comprises a power semiconductor die inserted in a cavity of a conductive body. In another embodiment, the electronic component comprises a power semiconductor die placed on a planar conductive body (i.e. not having a cavity). In both embodiments, the conductive body or conductive carrier may be for example a metal block, leadframe, copper block, printed circuit board (PCB), etc. The conductive body may provide a mechanical support function, an electric coupling function, and a heat removal function of the power semiconductor die accommodated in a cavity of the conductive body with surface access, or placed on a planar surface of the conductive body.

In an embodiment, the method comprises forming a hole in a main surface of the laminate carrier, and subsequently inserting an anchor block for anchoring the pin in the formed hole so that the anchor block is accessible at a main surface of the laminate carrier. For instance, the hole may be formed by routing. The anchor block may then be inserted as an inlay in the hole. When the anchor block extends up to a main surface of the laminate carrier, insertion of the pin in the anchor block is a very simple task.

In an embodiment, the method comprises forming a hole in the laminate carrier, and subsequently inserting the pin in the formed hole. For instance, a hole may be drilled in the laminate carrier which extends up to or into the anchor block. Thereafter, the pin may be simply inserted into the hole, for instance by pressing-fitting.

In an embodiment, a thickness of the laminate carrier is in a range between 100 μm and 2000 μm, for instance in a range between 100 μm and 500 μm. The laminate carrier may be shaped as a plate. In an embodiment, a thickness of the at least one electronic component is in a range between 50 μm and 200 μm. In an embodiment, a thickness of a conductive body having a cavity in which the at least one electronic component is accommodated is in a range between 250 μm and 1500 μm. A diameter of the pin may be at least 50 μm, in particular at least 500 μm.

In an embodiment, the package comprises at least one further electronic component mounted on (in particular directly on) or above (for instance with one or more further structures in between) the laminate carrier. In particular, said at least one further electronic component may be electrically coupled with at least one electrically conductive layer of the laminate carrier and/or with the at least one embedded electronic component. Thus, the package may be configured as a system with multiple surface mounted and/or embedded electronic components. In particular, it may be possible to electrically couple the embedded electronic component with the surface mounted electronic component. By taking this measure, even complex electronic assemblies may be manufactured.

In an embodiment, the at least one electronic component comprises at least one of the group consisting of a controller circuit, a driver circuit, and a power semiconductor circuit. All these circuits may be integrated into one semiconductor chip, or separately in different chips. For instance, a corresponding power semiconductor application may be realized by the chip(s), wherein integrated circuit elements of such a power semiconductor chip may comprise at least one transistor (in particular a MOSFET, metal oxide semiconductor field effect transistor), at least one diode, etc. In particular, circuits fulfilling a half-bridge function, a full-bridge function, etc., may be manufactured.

As substrate or wafer for the semiconductor chips, a semiconductor substrate, i.e. a silicon substrate, may be used. Alternatively, a silicon oxide or another insulator substrate may be provided. It is also possible to implement a germanium substrate or a III-V-semiconductor material. For instance, exemplary embodiments may be implemented in GaN or SiC technology.

The above and other objects, features and advantages of the present invention will become apparent from the following description and the appended claims, taken in conjunction with the accompanying drawings, in which like parts or elements are denoted by like reference numbers.

The illustration in the drawing is schematically and not to scale.

Before exemplary embodiments will be described in more detail referring to the figures, some general considerations will be summarized based on which exemplary embodiments have been developed.

A conventional electronic device may comprise a printed circuit board with at least one surface mounted electronic component and/or at least one embedded electronic component. For example, such an electronic device may form an electrical circuit for a driving application, for instance for a three phase inverter composed of three MOSFET half bridges suppling electrical energy to an electrical motor. An example of a corresponding drive application is an electrical scooter. Typically, the inverter board for the system may be built-up using an FR4 or IMS (insulated metal substrate) based PCB and discrete components such as power MOSFETs and passive components.

A well-designed layout is a key to high performance and efficiency, where reducing parasitic inductances to reduce voltage overshoots, while achieving good cooling of the components plays a major role in optimization. However, conventionally used technologies have limitations for an ideal layout. For example, FR4 boards being multilayer boards offer great versatility for electrical performance and temperature cycling on board (TCoB), but compromise in heat dissipation performance. IMS boards on the other hand, may outperform FR4 in thermal performance, but are typically limited to a single layer which limits the versatility of layout, and they compromise in TCoB and manufacturing effort.

A power board may interconnect to one or more additional boards (for instance comprising FR4) that may provide bulk capacitors and control elements (such as a microcontroller, gate drivers, etc.).

It may be desired to interconnect with more terminals arranged across the surface of the board.

According to an exemplary embodiment, an electronic device may be provided on the basis of a laminate carrier which may be formed as a board of a plurality of laminated electrically conductive and electrically insulating layers. One or more electronic components (for instance semiconductor power chips) may be embedded in a mechanically protected and electrically coupled way inside of the laminate carrier, for obtaining a compact and failure robust electronic device. For electrically coupling the laminate carrier including its embedded electronic component(s) with an electronic periphery (for instance for accomplishing a board-to-board interconnection), a partially laminate-embedded and partially protruding electrically conductive pin may be provided which allows to electrically and mechanically connect the electronic device with another electronic device or member. The one or more interconnection pin(s) may be anchored in the interior of the laminate carrier for providing mechanical stability and electric connectivity. In particular, the pin may be electrically coupled with at least one embedded electronic component for contributing to a transport of electric signals and/or electric power between the embedded electronic component and an electronic periphery of the electronic device. As a result, a laminate package may be obtained which can be electrically and mechanically connected with the environment in a simple way.

In particular, an electronic device according to an exemplary embodiment may be configured as power inlay-type interconnection circuit with one or more pins for PCB-type board-to-board interconnection.

Exemplary embodiments may allow to provide a full or partial system solution which can be fitted into a final application, for example an electrical scooter to supply required energy to an electric motor. Such an embodiment may offer the advantage of a reduced design or development effort for an inverter (or any other desired electronic application) which may result in a reduced manufacturing and design effort. For example, power MOSFET-type electronic components implemented according to exemplary embodiments may result in a further improved inverter system.

In terms of manufacturability, it may have technical disadvantages to surface mount devices on a PCB-type laminate carrier for an inlay board as this may require large amounts of vias under the terminal (or power connector). Furthermore, corresponding terminals can involve a high manufacturing effort. On the other hand, large terminals may use a considerable area on the laminate carrier or board. In order to overcome the above-mentioned and/or other shortcomings, an exemplary embodiment provides an improved approach of fabricating connections by prefabricating one or more pins along the surface of the PCB-type laminate carrier.

According to an exemplary embodiment, a method of preinstalling pins in a PCB-type laminate carrier may be executed for obtaining an advantageous interconnection of the PCB to another electronic member such as a further board. By preinstalling interconnection pins on the surface of the PCB, the pins may be used for interconnecting the PCB to the other board or the like.

For instance, a copper anchor (such as a copper bar) may be embedded in the PCB board with drilled hole in its interior for press fitting a pin therein. In such an embodiment, the shape of the pin can differ and can be provided with or without a mechanical support block. For the avoidance of doubt, the hole does not have to be in the actual center of an anchor block, especially when one anchor block holds several pins.

In another embodiment, it may be possible to drill a hole in a metal block (such as a leadframe) having a cavity in which a semiconductor chip is accommodated, wherein the metal block with semiconductor chip forms the embedded electronic component. Press-fitting the pin into the leadframe directly may be possible, wherein the shape of the pin can differ. Embodiments with or without a mechanical support block may be possible.

In still another embodiment, press-fitting an anchor block into a PCB board beside and against a metal block with semiconductor chip may be possible, wherein the anchor block has a hole drilled in its interior for press-fitting a pin after inserting the anchor block into the board. It may also be possible to preload the pin into the anchor block before inserting the anchor block.

In yet another embodiment, it may be possible to fabricate a blind via in a board with metalized sides and to insert the pin into said blind via by press-fitting. For example, this may be accomplished so that the pin does not protrude through the bottom of the board.

In an embodiment, it may be possible to fabricate a through via in a board with metalized sides and to insert the pin into said through via by press-fitting. For instance, this may be accomplished so that the pin protrudes fully through the board. Moreover, a heat sink may be machined so that the pin does not touch the heat sink.

FIG. 1 shows a cross-sectional view of an electronic device 100 according to an exemplary embodiment.

The illustrated electronic device 100 comprises a laminate carrier 102 comprising a laminated layer stack composed of a plurality of laminated layers 104, 106. Laminate carrier 102 is embodied as printed circuit board (PCB). In the illustrated example, the laminate carrier 102 comprises electrically insulating layers 106 which may be embodied as exterior prepreg layers and as a core 130 of FR4. Furthermore, the laminate carrier 102 comprises electrically conductive layers 104 embodied as copper layers on and in core 130 as well as on and in the prepreg layers. The electrically conductive layers 104 comprise horizontal traces and vertical through connections being interconnected with each other. A layer build-up in form of the electrically conductive layers 104 and the prepreg layers may be formed on both opposing main surfaces of core 130.

Furthermore, two electronic components 108, 108′ are embedded in the laminate carrier 102. The following description focuses on electronic component 108, whereas electronic component 108′ may be configured correspondingly. As shown, electronic component 108 is embedded in (for example central) core 130. The electronic component 108 comprises a bare power semiconductor die 134 which is inserted in a cavity of a conductive body 136. For example, the power semiconductor die 134 provides a transistor function (for instance may be embodied as a field effect transistor chip) or a diode function. The electrically conductive body 136 may be a metal block, such as a copper block, with a cavity machined in an upper main surface portion thereof. The power semiconductor die 134 is inserted into the cavity. The inlay-type electronic component 108 may then be inserted in a corresponding cavity, opening or through hole of core 130.

Furthermore, the electronic device 100 comprises an anchor block 112, which can be embodied as a metallic block (for instance made of copper). The anchor block 112 is arranged in a further cavity, opening or through hole of core 130 of the laminate carrier 102. For example, the anchor block 112 and the conductive bodies 136 of the electronic components 108, 108′ may be manufactured in a common process, for instance may form part of a common patterned metal plate or leadframe.

After embedding electronic components 108, 108′ and anchor block 112 in holes of core 130, the laminated layers 104, 106 may be formed above and below the core 130 with embedded electronic components 108, 108′ and with the embedded anchor block 112.

Furthermore, the electronic device 100 comprises an electrically conductive pin 110 extending partially inside the laminate carrier 102 and partially protruding beyond the laminate carrier 102. As shown, a lower end portion of the pin 110 extending into the laminate carrier 102 has a free end ending in the laminate carrier 102, more precisely in a blind hole of the anchor block 112 in the laminate carrier 102. In the shown configuration, the pin 110 is a solid pin. In this embodiment, the pin 110 has a constant diameter D over its entire vertical extension, both inside of the laminate carrier 102 and outside thereof. This may lead to a simple handling of the pin 110.

More specifically, the anchor block 112 is formed with a blind hole accommodating an end portion of the pin 110 for anchoring the pin 110 within the laminate carrier 102. Pin 110 may be guided through a further hole in the upper layers of the laminate carrier 102 and may then be inserted into the blind hole of the anchor block 112 by press-fitting until an end contact is made. This increases the mechanical stability of the pin 110 in the laminate carrier 102. The mentioned hole in the upper layers of the laminate carrier 102 and the blind hole in the anchor block 112 may be in flush so that the pin 110 may be simply guided through the aligned holes.

Advantageously, the pin 110 is electrically coupled with the electronic component 108 via electrically conductive layers 104 of the laminate carrier 102 and via the anchor block 112. More specifically, said coupling may be accomplished via a redistribution layer 128 of the laminate carrier 102. As shown, the anchor block 112 is electrically coupled with the electronic component 108 via electrically conductive layers 104 of the laminate carrier 102. This configuration may achieve, for example, a high power density and a superior switching behavior of an inverter formed on the basis of electronic components 108, 108′.

The portion of pin 110 protruding beyond the upper main surface of the laminate carrier 102 may be used for establishing an electromechanical connection with another printed circuit board (not shown), an electric connection cable, or any other electronic member. Hence, a mechanical connection between the electronic device 100 and said other electronic member may be established by the protruding portion of the pin 110. For instance, such a mechanical connection may be a solder connection or a screw connection. At the same time, the pin 110 may establish an electric coupling of the component 108 with said electronic member. Hence, electric signals (such as control signals) and/or electric power may be transmitted between the component 108 and said electronic member via said pin 110. Thus, the electronic device 100 may be configured so that electric signals and/or electric power is transmitted by the pin 110 during operation of the electronic device 100.

Advantageously, the pin 110 may be fixed in the laminate carrier 102 and in the blind hole of the anchor block 112 by a press-fitting connection. For this purpose, the electronic component 108 and the anchor block 112 for anchoring the pin 110 may be embedded in the laminate carrier 102. Moreover, a hole may be formed in the laminate carrier 102 and in the anchor block 112. Subsequently, the pin 110 may be inserted in the formed hole so as to be anchored, with a press-fitting connection, in the anchor block 112 and the laminated layers 104, 106.

As an alternative to said press-fitting connection, pin 110 may also be anchored in anchor block 112 and/or laminate carrier 102 by screwing, soldering, or the like.

The described electromechanical connection between the electronic device 100 and the electronic member may be accomplished via the upper side of the electronic device 100 according to FIG. 1. Via the lower main surface of the electronic device 100 according to FIG. 1, heat generated by the embedded electronic components 108, 108′ during operation of the electronic device 100 may be dissipated, as will be described in the following:

As shown, the electronic device 100 comprises a thermal interface layer 124 attached to the bottom of the laminated layer stack forming laminate carrier 102. For instance, the thermal interface layer 124 may be made of a thermal interface material (TIM), for instance thermal paste. A heat sink 126 may be arranged on the thermal interface layer 124 and thus also at a main surface of the laminate carrier 102 facing away from the portion of the pin 110 protruding beyond the laminate carrier 102.

As already mentioned, the embodiment of FIG. 1 comprises the embedded independent anchor block 112, which may be for example a copper bar. Anchor block 112 may have the same thickness as the conductive bodies 136 (which may be leadframe structures) of the electronic components 108, 108′.

A drill hole may be formed from the top surface of the laminate carrier 102 to the anchor block 112. The hole depth may be either slightly less than the anchor block thickness, or may penetrate all the way through the anchor block 112, but does not reach all the way through the board-type laminate carrier 102. Preferably, the pin 110 does not reach a neighboring layer below the anchor plate 112.

The pin 110 may be applied (for example by press-fitting) into the anchor block 112 through the top of the board-type laminate carrier 102.

Depending on size and shape of the anchor block 112, one anchor block 112 can be provided for one or several pins 110. Thus, a plurality of anchor blocks 112 may be embedded in the laminate carrier 102 (not shown).

The anchor block 112 can be further connected to neighboring electrically conductive layers 104 by laser vias and/or other vertical through connections and/or traces, the same is true for the leadframe-type conductive bodies 136 of the electronic components 108, 108′ and for the die 134 itself (the pads on the die 134 can be connected to neighboring layers).

Length and shape of the pin(s) 110 above the laminate carrier 102 can be adapted according to system needs.

A possible connection to a drain layer is indicated by reference sign 160 in FIG. 1. Instead of a drain connection, an anchor-pin combination can also be coupled to a source terminal, a gate terminal, or another kind of electric terminal (for instance an anode terminal or a cathode terminal of a diode) of a connected electronic component 108, 108′.

FIG. 2 shows a cross-sectional view of an electronic device 100 according to another exemplary embodiment.

The embodiment of FIG. 2 differs from the embodiment of FIG. 1 in particular in that, according to FIG. 2, the pin 110 has a wider portion 118 partially inside the laminate carrier 102 and partially protruding beyond the laminate carrier 102, and has a narrower portion 120 completely inside the laminate carrier 102. Thus, pin 110 according to FIG. 2 has a stepped profile with two cylindrical sections of different diameters. Hence, FIG. 2 shows an embodiment in which pin 110 is provided with wider top protrusion. To put it shortly, the described configuration of pin 110 may lead to a strain relief function of the pin 110 itself. Thus, the press-fitting pin 110 of FIG. 2 is shaped in such way that its wider portion 118 offers enhanced mechanical support or stability inside the PCB-type laminate carrier 102. The wider portion 118 only protrudes through the top of the board, whereas the narrower portion 120 is configured for providing an anchor press-fitting connection.

Before press-fitting the pin 110 through the outer layers 104, 106 of the laminate carrier 102 into a blind hole in anchor block 112, the mentioned two holes may be predrilled, i.e. the deeper narrower, and the wider shallower one, to accommodate the pin 110 with the described shape. Depths and lengths of portions 118, 120 of pin 110 are design parameters which may be selected for adjusting or fine-tuning the described functionality.

FIG. 3 shows a cross-sectional view of an electronic device 100 according to another exemplary embodiment.

The embodiment of FIG. 3 differs from the embodiment of FIG. 2 in particular in that, according to FIG. 3, the electronic device 100 comprises a strain relief structure 114 arranged in a surface portion of the laminate carrier 102 above the anchor block 112 and below a portion of the pin 110 protruding beyond the laminate carrier 102. More specifically, the strain relief structure 114 of FIG. 3 is arranged in a surface portion of the laminate carrier 102 with surface access. According to FIG. 3, the pin 110 has a wider portion 118 completely protruding beyond the laminate carrier 102, and has a narrower portion 120 partially protruding beyond and partially inside the laminate carrier 102, the strain relief structure 114 and the anchor block 112.

The strain relief structure 114 of FIG. 3 is configured as metallic block with through hole through which pin 110 is guided. Thereby, the strain relief structure 114 is configured for preventing the pin 110 and a surrounding portion of the laminate carrier 102 from breaking when exerting a mechanical force, for instance when bending the pin 110 relatively to the laminate carrier 102. By the strain relief structure 114, pin 110 is held in place more firmly, and the electric contact provided by pin 110 is protected and strengthened.

Hence, for further enhancing the mechanical stability, a copper (or other material, preferably metallic material) block is inserted in laminate carrier 102 for forming the strain relief structure 114. This may be accomplished by machining the top part of the PCB and inserting the prefabricated block in the opening (for example by gluing or pressing). A hole may then be drilled through the support block forming the strain relief structure 114 up to the anchor block 112. The pin 110 may then be inserted through the strain relief structure 114 into the blind hole in anchor block 112 for establishing a press-fitting connection.

FIG. 4 shows a cross-sectional view of an electronic device 100 according to another exemplary embodiment.

The embodiment of FIG. 4 differs from the embodiment of FIG. 1 in particular in that, according to FIG. 4, the anchor block 112 is formed as integral part of the electronic component 108. More specifically, anchor block 112 of FIG. 4 is embodied as a portion of the conductive body 136 of the electronic component 108. As mentioned above, a cavity in conductive body 136 serves for accommodating bare die 134. In addition, a blind hole in conductive body 136 functions for receiving an end of pin 110, for example for establishing a press-fitting connection in between. By integrally forming anchor block 112 and conductive body 136 as one common metal block, a simple and compact design may be achieved. Furthermore, electric paths may be kept short, which may lead to high signal quality and low losses. As a result of the configuration of FIG. 4, the pin 110 is directly electrically coupled with the electronic component 108 by establishing a press-fitting connection in between. Hence, the leadframe structure forming the conductive body 136 serves simultaneously as anchor block 112 for pin 110 and for accommodating bare die 134. The pin 110 may be inserted into the leadframe structure of the electronic component 108 by press-fitting.

According to FIG. 4, assembly of pin 110 may be accomplished by drilling and/or milling after the PCB-type laminate carrier 102 is finished. The pin 110 may be placed by press-fitting into the conductive body 136.

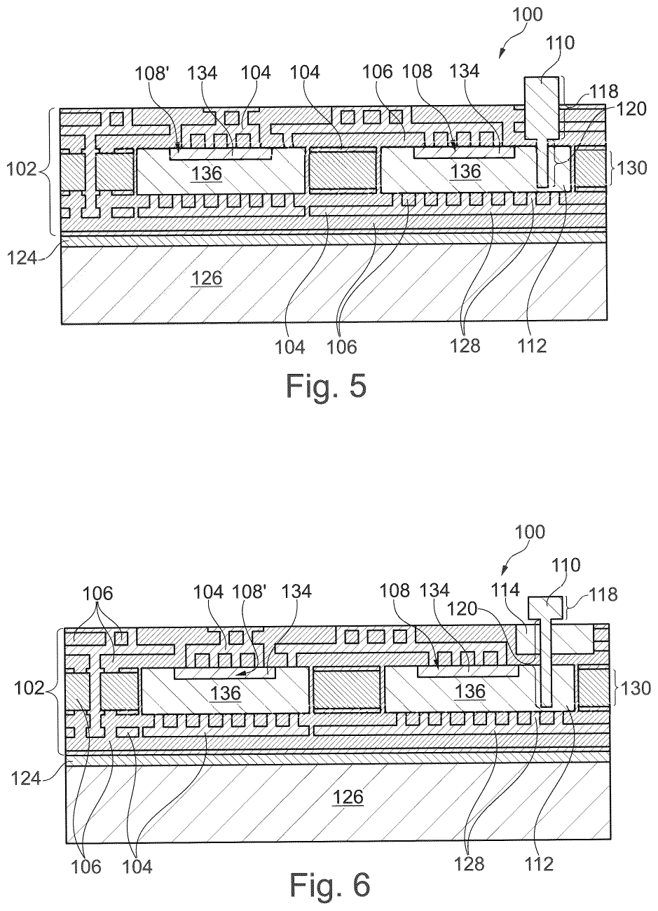

FIG. 5 shows a cross-sectional view of an electronic device 100 according to another exemplary embodiment.

The embodiment of FIG. 5 differs from the embodiment of FIG. 4 in particular in that, according to FIG. 5, the pin 110 has a wider portion 118 partially inside the laminate carrier 102 and partially protruding beyond the laminate carrier 102, and has a narrower portion 120 partially inside the laminate carrier 102 and partially inside the portion of the conductive body 136 constituting the anchor block 112. Thus, pin 110 according to FIG. 5 has a stepped profile with two cylindrical sections of different diameters. In the described configuration, pin 110 may also function as a strain relief structure without rendering formation of a press-fitting connection difficult.

According to FIG. 5, conductive block 136 of electronic component 108 is used as anchor block 112. During assembly, pin 110 may be inserted into the leadframe structure constituting conductive block 136 by press-fitting. For assembly, drilling and/or milling may be carried out after formation of the PCB is finished. A second drilling process may be executed extending into the conductive block 136. Then, a press-fitting pin placement into the conductive block 136 may be carried out.

FIG. 6 shows a cross-sectional view of an electronic device 100 according to another exemplary embodiment.

The embodiment of FIG. 6 differs from the embodiment of FIG. 5 in particular in that, according to FIG. 6, the pin 110 has its wider portion 118 completely protruding beyond the laminate carrier 102, and has its narrower portion 120 partially protruding beyond the laminate carrier 102, partially extending through strain relief structure 114, partially extending inside the laminate carrier 102, and partially extending in the conductive body 136 containing anchor block 112. This provides a highly stable configuration of pin 110 with excellent strain relief function.

According to FIG. 6, conductive body 136 is co-used as anchor block 112. For this purpose, the pin 110 is inserted into the leadframe structure constituting conductive body 136 by press-fitting.

For manufacture, a first drilling and/or milling process may be executed after formation of the PCB is finished (for example bigger than the pin diameter). A second drilling may be carried out into the conductive block 136. The pin 110 may be placed into the conductive block 136 by press-fitting. The hole may be filled with glue or similar.

FIG. 7 shows a cross-sectional view of an electronic device 100 according to another exemplary embodiment.

The embodiment of FIG. 7 differs from the embodiment of FIG. 1 in particular in that, according to FIG. 7, the anchor block 112 is directly electrically coupled with the electronic component 108 by mutually contacting facing sidewalls of the anchor block 112 and of the electronic component 108. This leads to short signal paths and a good signal quality. Furthermore, the described configuration is mechanically highly stable.

For manufacturing the electronic device 100 according to FIG. 7, it may be possible to form a hole in a main surface of the laminate carrier 102, and subsequently insert an anchor block 112 for anchoring the pin 110 in the formed hole so that the anchor block 112 is accessible at a main surface of the laminate carrier 102. The anchor block 100 may be laterally pressed against the conductive body 136 of the electronic component 108. This may lead to short electric paths yielding low loss and high signal integrity.

What concerns manufacture of the electronic device 100 according to FIG. 7, the anchor block 112 may be inserted after the laminate carrier 102 is fabricated. This may be accomplished by drilling or milling the opening from top in a way that it exposes a side of the conductive body 136 (or a plurality of conductive bodies 136). The anchor block 112 may be inserted or press fitted in the laminate carrier 102, and pressed against the side of the leadframe structure constituting conductive body 136. The pin(s) 110 may then be inserted into anchor block 112.

Alternatively, the pin(s) 110 can be prefabricated together with the anchor block 112 before insertion, or can be fabricated as a single piece.

FIG. 8 shows a cross-sectional view of an electronic device 100 according to another exemplary embodiment.

The embodiment of FIG. 8 differs from the embodiment of FIG. 1 in particular in that, according to FIG. 8, an anchor sleeve 116 is provided (rather than an anchor block 112) which in arranged in or forms part of the laminate carrier 102 and which has a blind hole accommodating an end portion of the pin 110.

According to FIG. 8, pin 110 may be inserted into the anchor sleeve 116 by press-fitting, without anchor block 112. Thus, the embodiment of FIG. 9 is compact and simple. The pin 110 may be inserted into a blind via or blind pad in form of anchor sleeve 116. The corresponding via may be fabricated with the laminate carrier 102 so that it is metalized on the vertical sides thereof.

Also according to FIG. 8, pin 110 may be mounted by press-fitting, wherein however the pin 110 does not protrude through the bottom of the laminate carrier 102 according to FIG. 8.

FIG. 9 shows a cross-sectional view of an electronic device 100 according to another exemplary embodiment.

The embodiment of FIG. 9 differs from the embodiment of FIG. 8 in particular in that, according to FIG. 9, the anchor sleeve 116 arranged in or forming part of the laminate carrier 102 has a through hole accommodating a portion of the pin 110. Consequently, pin 110 of FIG. 9 protrudes through the entire laminate carrier 102 and protrudes beyond both opposing main surfaces thereof. Thus, both opposing end portions of the pin 110 protrude beyond the laminate carrier 102, wherein a portion of the pin 110 extends inside the full thickness of the laminate carrier 102.

The pin 110 may be inserted through the entire board without anchor and may be fixed by establishing a press-fitting connection. Thus, pin 110 protrudes fully through the laminate carrier 102 according to FIG. 9.

During assembly, the pin 110 may be inserted into a through hole pad in form of anchor sleeve 116. This pad or anchor sleeve 116 may be fabricated with the laminate carrier 102 and can be metalized on the vertical sides.

As shown in FIG. 9, the heat sink 126 may be provided with a recess 170 for accommodating an end of pin 110 protruding beyond the lower main surface of laminate carrier 102. This may be accomplished by additionally machining heat sink 126 to prevent the heat sink 126 from touching the protruding pin 110.

FIG. 10 shows a cross-sectional view of an electronic device 100 according to another exemplary embodiment.

As in the previously described embodiments, the electronic device 100 comprises an electronic component 108 embedded in an interior of laminate carrier 102. At least one electrically conductive layer 104 surrounded by electrically insulating layers 106 of the laminated stack of laminate carrier 102 is connected electrically with the embedded electronic component 108. Furthermore, said electrically conductive layer 104 may also be coupled with electrically conductive pins 110, 110′ which extend side-by-side and parallel to each other partially inside laminate carrier 102 and partially protrude beyond laminate carrier 102. Another electronic member 132, such as another PCB, can be connected electromechanically by the pins 110, 110′ with laminate carrier 102 and electronic component 108 embedded therein. In the shown embodiment, such a connection may be formed by electrically conductive connection medium 172, such as solder, which mechanically and electrically couples the pins 110, 110′ with the electronic member 132.

Thus, according to FIG. 10, the electronic device 100 comprises additionally the further electrically conductive pin 110′ extending partially inside the laminate carrier 102 and partially protruding beyond the laminate carrier 102 and being electrically coupled with the electronic component 108 embedded in the laminate carrier 102. The electronic member 132 is coupled with the laminate carrier 102 by portions of the pins 110, 110′ protruding beyond the laminate carrier 102. As an alternative to the illustrated solder coupling, the electromechanical coupling between the electronic member 132 and the laminate carrier 102 may also be accomplished by a screw coupling, a further press fit coupling, and/or a plug-in coupling.

As illustrated in FIG. 10, the above-mentioned heat sink 126 may comprise a thermally conductive plate 176 from which a plurality of cooling fins 178, also made of a thermally conductive material, extend downwardly. Preferably, heat sink 126 may be made of a metal or a ceramic to provide a high thermal conductivity. Heat generated by the electronic component 108 may be dissipated via the electrically insulating and thermally conductive thermal interface layer 124 and the heat sink 126 to an environment, for instance by air cooling. It is also possible that the heat sink 126 is embodied as a liquid cooled heat sink (for instance may be a water cooler), etc.

It should be noted that the term “comprising” does not exclude other elements or features and the “a” or “an” does not exclude a plurality. Also elements described in association with different embodiments may be combined. It should also be noted that reference signs shall not be construed as limiting the scope of the claims. Moreover, the scope of the present application is not intended to be limited to the particular embodiments of the process, machine, manufacture, composition of matter, means, methods and steps described in the specification. Accordingly, the appended claims are intended to include within their scope such processes, machines, manufacture, compositions of matter, means, methods, or steps.

What is claimed is:

1. An electronic device, comprising:
a laminate carrier comprising a plurality of laminated layers;
an electronic component embedded in the laminate carrier; and
an at least partially electrically conductive pin extending partially inside the laminate carrier and partially protruding beyond the laminate carrier;
wherein the pin is electrically coupled with the electronic component.

2. The electronic device according to claim 1, wherein the pin is fixed in the laminate carrier by a press-fitting connection.

3. The electronic device according to claim 1, comprising an anchor block which in arranged in the laminate carrier and which has a hole accommodating an end portion of the pin for anchoring the pin in the laminate carrier.

4. The electronic device according to claim 3, comprising one of the following features:
wherein the anchor block is directly electrically coupled with the electronic component, for example by mutually contacting sidewalls of the anchor block and of the electronic component;
wherein the anchor block is electrically coupled with the electronic component via at least one electrically conductive layer of the laminate carrier; and
wherein the anchor block forms part of the electronic component.

5. The electronic device according to claim 3, comprising a strain relief structure arranged in the laminate carrier between the anchor block and a portion of the pin protruding beyond the laminate carrier.

6. The electronic device according to claim 1, comprising an anchor sleeve which in arranged in or forms part of the laminate carrier and which has a blind hole accommodating an end portion of the pin or which has a through hole accommodating a portion of the pin.

7. The electronic device according to claim 1, wherein the pin has a wider portion at least partially protruding beyond the laminate carrier and a narrower portion at least partially inside the laminate carrier.

8. The electronic device according to claim 1, wherein the pin has a constant diameter over its entire extension.

9. The electronic device according to claim 1, configured so that electric signals and/or electric power is transmitted by the pin during operation of the electronic device.

10. The electronic device according to claim 1, comprising at least one of the following features:
the electronic device comprises at least one further electronic component embedded in the laminate carrier;
the electronic device comprises at least one further at least partially electrically conductive pin extending partially inside the laminate carrier and partially protruding beyond the laminate carrier and being electrically coupled with the electronic component and/or with at least one further electronic component embedded in the laminate carrier.

11. The electronic device according to claim 1, comprising at least one of the following features:
comprising a thermal interface layer and/or a heat sink arranged at a main surface of the laminate carrier facing away from a portion of the pin protruding beyond the laminate carrier;
wherein an end portion of the pin extending into the laminate carrier has a free end ending in the laminate carrier;
wherein both opposing end portions of the pin protrude beyond the laminate carrier and a portion of the pin extends inside the laminate carrier;
the pin is directly electrically coupled with the electronic component;
the pin is electrically coupled with the electronic component via an at least partially electrically conductive anchor block in which the pin is inserted;
the pin is electrically coupled with the electronic component via at least one electrically conductive layer of the laminate carrier, for example via a redistribution layer of the laminate carrier.

12. The electronic device according to claim 1, wherein the electronic component is embedded in a core in an interior of the laminate carrier.

13. The electronic device according to claim 1, comprising an electronic member being coupled, for example being electromechanically coupled, with the laminate carrier by a portion of the pin protruding beyond the laminate carrier.

14. The electronic device according to claim 13, wherein the electronic member comprises at least one of an electronic board, an electric cable, and a metallic block.

15. The electronic device according to claim 13, wherein the coupling between the electronic member and the laminate carrier comprises at least one of the group comprising a solder coupling, a screw coupling, a press fit coupling, and a plug-in coupling.

16. The electronic device according to claim 1, comprising at least one of the following features:
wherein the pin is a solid pin or a sleeve;
wherein the pin has a springy portion.

17. The electronic device according to claim 1, wherein the electronic component is a bare power semiconductor die.

18. The electronic device according to claim 1 wherein the electronic component comprises a power semiconductor die inserted in a cavity of a conductive body.

19. A method of manufacturing an electronic device, the method comprising:
embedding an electronic component in a laminate carrier which comprises a plurality of laminated layers;
forming an at least partially electrically conductive pin which extends partially inside the laminate carrier and partially protrudes beyond the laminate carrier; and
electrically coupling the pin with the electronic component.

20. The method according to claim 19, comprising at least one of the following features:
wherein the method comprises inserting and fixing the pin in the laminate carrier by press-fitting;
wherein the method comprises embedding in the laminate carrier the electronic component and an anchor block for anchoring the pin;
wherein the method comprises forming a hole in a main surface of the laminate carrier, and subsequently inserting an anchor block for anchoring the pin in the formed hole so that the anchor block is accessible at a main surface of the laminate carrier;
wherein the method comprises forming a hole in the laminate carrier, and subsequently inserting the pin in the formed hole.
